(19) United States
(12) Patent Application Publication
(10) Pub. No.: US 2009/0072297 A1
(43) Pub. Date: Mar. 19, 2009

(54) Multibit electro-mechanical memory device and method of manufacturing the same

(75) Inventors: Ji-Myoung Lee, Yongin-si (KR); Min-Sang Kim, Seoul (KR); Eun-Jung Yun, Seoul (KR); Sung-Young Lee, Yongin-si (KR); In-Hyuk Choi, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/154,474

(22) Filed: May 23, 2008

(30) Foreign Application Priority Data
May 23, 2007 (KR) 10-2007-0050346

(51) Int. Cl. H01L 21/28; H01L 29/792

(52) U.S. Cl. 257/324; 438/591; 257/E29.309; 257/E21.21

(57) ABSTRACT

A memory device comprises a cantilever electrode comprising a first portion that is supported by a pad electrode, and that extends from the pad electrode, and further comprising a second portion that arches over an upper part of the lower word line, wherein a lower void is between the second portion of the cantilever electrode and the lower word line, and wherein the second portion of the cantilever electrode, in a first position, is curved, wherein a trap site extends above the cantilever electrode, the trap site separated from the cantilever electrode by an upper void, and wherein an upper word line on the trap site receives a charge that enables the second portion of the cantilever electrode, in a second position, to be curved toward the trap site.

### CROSS REFERENCE TO RELATED APPLICATIONS

This application claims priority under 35 U.S.C. § 119 from Korean Patent Application 10-2007-0050346, filed in the Korean Intellectual Property Office on May 23, 2007, the contents of which are hereby incorporated by reference in their entirety for all purposes as if fully set forth herein.

### FIELD OF THE INVENTION

The present invention relates to a semiconductor memory device and method of manufacturing the same. More particularly, the present invention relates to a multibit electro-mechanical memory device and a method of manufacturing the same, for programming and reading data by a switching operation performed by cantilever electrodes that are formed symmetrically relative to a trench.

### BACKGROUND OF THE INVENTION

Typically, a memory device that stores data is largely classified as either a volatile semiconductor memory device or a nonvolatile semiconductor memory device. The volatile memory device principally represented as a DRAM (Dynamic Random Access Memory) or a SRAM (Static Random Access Memory), etc., is fast with regard to the input/output operation of data, but has a shortcoming in that stored contents are lost when a power supply is stopped. The nonvolatile memory device principally represented as EPROM (Erasable Programmable Read Only Memory) or EEPROM (Electrically Erasable Programmable Read Only Memory), etc., on the other hand, is slow with regard to the input/output operation of data, but has the benefit of maintaining intact the stored data even when a power supply is interrupted.

A conventional memory device commonly employs a MOSFET (Metal Oxide Semiconductor Field Effect Transistor) based on MOS (Metal Oxide Semiconductor) technology. For example, a stack gate-type transistor memory device of a stack structure adapted on a semiconductor substrate formed of silicon material, and a transistor memory device of a trench gate-type having a structure buried in the semiconductor substrate, are under development. However, a width and length of the channel in the MOSFET must be formed with a sufficient minimum required length to suppress a short-channel effect. Further, a thickness of gate insulation layer formed between a gate electrode formed on the channel and the semiconductor substrate must be extremely thin. Due to such fundamental problems, it is difficult to realize a memory device of a nano-level ultra microstructure for the MOSFET.

Memory devices are being researched to replace the MOSFET described above with new devices that do not experience the abovementioned undesirable characteristics. Micro electro-mechanical system (MEMS) and nano electro-mechanical system (NEMS) technology applied to suspend bridge memory (SBM) are becoming an issue. One such nonvolatile memory device using the MEMS technology is disclosed in U.S. Pat. No. 6,054,745, incorporated herein by reference in its entirety.

FIG. 1 is a sectional view of a memory device according to a conventional art.

As shown in FIG. 1, a conventional memory device is obtained by forming an FET (Field Effect Transistor) sensor 221, attractive electrode part 223 and cantilever electrode supporter 225, which are distinguished from one another, on a shallow trench isolation (STI) layer 224 formed on a substrate. The FET sensor 221 comprises a polysilicon gate electrode 230 and a source/drain region 227. A cantilever electrode 240 is also formed such that one side of the cantilever electrode 240 is supported by, and electrically connected to, the cantilever electrode supporter 225, wherein the cantilever electrode 240 is distanced by a predetermined height from the attractive electrode part 223 and the FET sensor 221. The cantilever electrode 240 can be curved toward the attractive electrode 232 by an electric field induced by the attractive electrode part 223. Then, even when the electric field induced by the attractive electrode part 223 is eliminated, the cantilever electrode 240 can maintain its curved state by an electric field induced from captured electrons held by a polysilicon gate electrode 230 of the FET sensor 221. For example, the polysilicon gate electrode 230 corresponds to a floating electrode of a flash memory device for capturing electrons tunneled through a tunnel oxide layer that is formed of a dielectric formed on a source-drain region 227 of the FET sensor 221. The attractive electrode part 223 and the cantilever electrode supporter 225 are formed of the same polysilicon material 232 as the polysilicon gate electrode 230. The elements under attractive electrode part 223 and the cantilever electrode supporter 225, respectively, are fabricated to be co-planar with each other in the same process, for example, as disclosed in U.S. Pat. No. 6,054,749, incorporated herein in its entirety by reference. The cantilever electrode 240 is also formed of a same or similar polysilicon material as that of the cantilever electrode supporter 225.

That is, in a conventional memory device, a nonvolatile memory device can include an attractive electrode 232 for curving the cantilever electrode 240 by an electromagnetic force, and an FET sensor 221 including the gate electrode 230 for maintaining the curved state of the cantilever electrode 240, in a lower part of the cantilever electrode 240.

However, a conventional memory device and method of manufacturing the same such as that shown in FIG. 1 have the following problems.

In the conventional memory device, cantilever electrode 240 switched into a vertical direction is adapted horizontally, that is, in parallel with substrate 222, thus, it is difficult to reduce a plane size of the memory device, and so an integration of the memory device decreases.

Further, in the conventional memory device, when the length of cantilever electrode 240 is reduced to below a given level, a switching length becomes large as compared with the length of the cantilever electrode 240, thus the cantilever electrode 240 is easy to be broken down, and so reliability of memory devices decreases.

Further, in the conventional memory device, only 1 bit of data is programmed or read out per one unit cell comprised of the cantilever electrode 240, attractive electrode 232 and FET sensor 221, and thus it is difficult to store multibit data.

### SUMMARY OF THE INVENTION

Some embodiments of the invention provide a multibit electro-mechanical memory device and method of manufacturing the same, which is capable of reducing a plane size of memory device and increasing an integration of memory devices. Even when the length of cantilever electrode is reduced to below a given level, a movement distance does not become large as compared with the length of cantilever electrode, and furthermore the cantilever electrode is prevented from being easy to be broken down, thereby increasing reliability in memory devices. Two or more bits of data can be input/output for one unit cell.

In an aspect, a memory device comprises a substrate; a bit line extending in a first direction on the substrate; a lower word line extending in a second direction, the lower word line isolated from the bit line; a pad electrode isolated from a sidewall of the lower word line and electrically coupled to the bit line; a cantilever electrode comprising a first portion that is supported by the pad electrode, and that extends from the pad electrode in a third direction that is transverse to the first and second directions, and further comprising a second portion that arches over an upper part of the lower word line, wherein a lower void is between the second portion of the cantilever electrode and the lower word line, and wherein the second portion of the cantilever electrode, in a first position, is curved in the first direction; a trap site extending in the second direction above the cantilever electrode, the trap site separated from the cantilever electrode by an upper void; and an upper word line on the trap site, the upper word line receiving a charge that enables the second portion of the cantilever electrode, in a second position, to be curved toward the trap site.

In an embodiment, a top surface of the pad electrode is at a same level as a top surface of the lower word line or at a level lower than the top surface of the lower word line.

In an embodiment, at least a portion of the lower void is adjacent a side face of the lower word line.

In another aspect, a multibit electro-mechanical memory device comprises a substrate; a bit line extending in a first direction on the substrate; a first interlayer insulating layer on the bit line, the first interlayer insulating layer extending in a second direction perpendicular to the first direction, and insulating the bit line; first and second lower word lines formed on the first interlayer insulating layer; a second interlayer insulating layer between the sidewalls of the first and second portions of the first interlayer insulating layer and between sidewalls of the first and second lower word lines; a pad electrode electrically coupled to the bit line by a contact hole formed in the second interlayer insulating layer; first and second cantilever electrodes arching over first and second lower voids that are between the first and second cantilever electrodes and the first and second word lines, wherein the first and second cantilever electrodes are separated from each other by a trench, and are curved in a third direction that is transverse to the first and second directions; a third interlayer insulating layer on the pad electrode; first and second trap sites supported by the third interlayer insulating layer, wherein first and second upper voids are between the first and second trap sites and the first and second cantilever electrodes, respectively; and first and second upper word lines on the first and second trap sites.

In an embodiment, a top surface of the pad electrode is at a same level as a top surface of the lower word line or at a level lower than the top surface of the lower word line.

In an embodiment, at least a portion of the lower void is adjacent a side face of the lower word line.

In an embodiment, the first and second trap sites each have a stacked structure comprising a first silicon oxide layer, a silicon nitride layer, and a second silicon oxide layer.

In an embodiment, a fourth interlayer insulating layer seals the trench at an upper end part of the trench.

In another aspect, a method of manufacturing a multibit electro-mechanical memory device comprises forming a bit line in a first direction on a substrate; forming a first interlayer insulating layer, a lower word line and a first sacrifice layer on the substrate in a second direction perpendicular to the bit line; forming a second interlayer insulating layer on at least a portion of a sidewall of the first interlayer insulating layer and the lower word line, and planarizing the second interlayer insulating layer; forming a spacer on the second interlayer insulating layer, the spacer abutting a remaining portion of the sidewall of the lower word line, wherein an upper portion of the spacer abuts a sidewall of the first sacrifice layer; forming a contact hole that selectively exposes the bit line by removing a portion of the second interlayer insulating layer by an etching method using the spacer as a mask layer; forming a pad electrode inside the contact hole; forming a cantilever electrode that is coupled to an upper part of the pad electrode and that conforms to an upper surface of the first sacrifice layer and the spacer; forming a second sacrifice layer, a trap site, and an upper word line in the second direction on the cantilever electrode; forming a third interlayer insulating layer on the pad electrode to be in contact with sidewalls of the second sacrifice layer, the trap site, and the cantilever electrode; forming a trench to expose the first interlayer insulating layer by removing, in the second direction, portions of the upper word line, the trap site, the second sacrifice layer, the cantilever electrode, the first sacrifice layer and the lower word line; and forming a void above and below the cantilever electrode by removing the first sacrifice layer, the spacer and the second sacrifice layer exposed to the trench.

In an embodiment, forming the second interlayer insulating layer comprises forming a silicon oxide layer having a given thickness on an entire face of the substrate on which the first interlayer insulating layer, the lower word line and the first sacrifice layer have been formed; removing the silicon oxide layer to become planarized to expose the first sacrifice layer; and removing the silicon oxide layer to partially expose the sidewalls of the first sacrifice layer and the lower word line.

In an embodiment, forming the spacer comprises forming a thin film of polysilicon material with a given thickness on an entire face of the substrate on which the second interlayer insulating layer and the first sacrifice layer have been formed; and removing the thin film through an anisotropic etching method.

In an embodiment, the contact hole is formed by removing the spacer in a self-alignment of a dry etching method using the spacer as a mask layer.

In an embodiment, the dry etching method uses HBr gas as a source gas having a high etching selection ratio for silicon oxide as compared with polysilicon when the spacer is formed of polysilicon and the second interlayer insulating layer is formed of silicon oxide.

In an embodiment, the pad electrode is formed by forming a conductive metal filling in the contact hole, removing the conductive metal to be planarized so as to expose the first sacrifice layer, and selectively etching the conductive metal to expose the spacer.

In an embodiment, a titanium or titanium nitride layer is formed on the bit line exposed to the contact hole before forming the pad electrode.

In an embodiment, when the spacer, the first sacrifice layer and the second sacrifice layer are formed of polysilicon, the polysilicon is removed through an isotropic etching of a wet or dry etching method.

In an embodiment, an isotropic etching solution used in the wet etching method contains nitric acid, HF and mixture solution got by mixing acetic acid and deionized-water by a given density, and isotropic etching solution used in the dry etching method contains gas of fluoridation carbon group formed of CF₄ or CHF₃.

In an embodiment, a fourth interlayer insulating layer is formed shielding an upper part of the trench to seal the interior of the trench.

### BRIEF DESCRIPTION OF THE DRAWINGS

The above and other features and advantages of the present invention will become more apparent to those of ordinary skill in the art by describing in detail preferred embodiments thereof with reference to the attached drawings. The embodiments depicted therein are provided by way of example, not by way of limitation, wherein like reference numerals refer to the same or similar elements. The drawings are not necessarily to scale, emphasis instead being placed upon illustrating aspects of the invention. In the drawings:

FIG. 1 is a sectional view of a memory device according to a conventional art;

FIG. 2 is a perspective view of a multibit electro-mechanical memory device, according to an embodiment of the invention;

FIG. 3 is a sectional view taken along a line I˜I′ of FIG. 2;

FIG. 4 is a sectional view of a stacked structure of the multibit electro-mechanical memory device shown in FIG. 3;

FIGS. 5A to 6B are sectional views providing operations of programming to or reading data out of a multibit electro-mechanical memory device, according to an embodiment of the invention;

FIG. 7 is a graph illustrating a correlation between a voltage applied through a bit line and upper word line and a movement distance of the tip of a cantilever electrode in a multibit electro-mechanical memory device, according to an embodiment of the invention; and

FIGS. 8A to 18B are sectional views of processes provided to manufacture a multibit electro-mechanical memory device according to an embodiment of the invention.

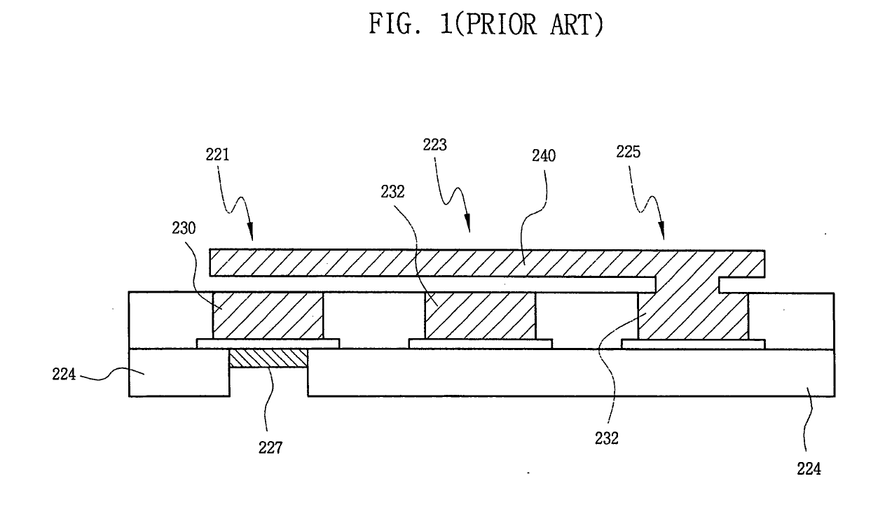

### DETAILED DESCRIPTION OF THE INVENTION

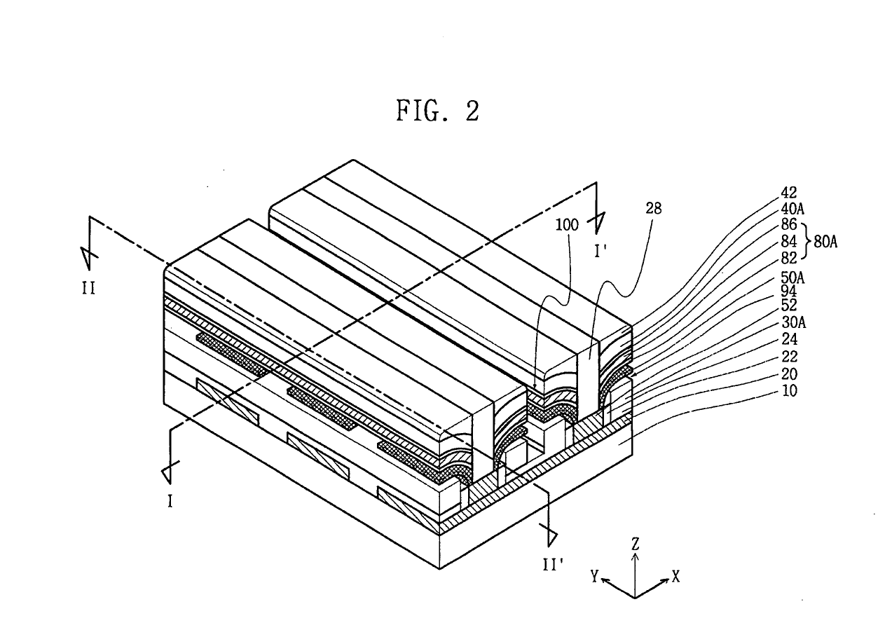

The present invention now will be described more fully hereinafter with reference to FIGS. 2 to 18B, in which embodiments of the invention are shown. This invention may, however, be embodied in many different forms and should not be construed as limited to the embodiments set forth herein. Rather these embodiments are provided so that this disclosure will be thorough and complete, and will fully convey the scope of the invention to those skilled in the art.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein. Exemplary embodiments of the present invention are more fully described below with reference to FIGS. 2 to 18B. This invention may, however, be embodied in many different forms and should not be construed as being limited to the exemplary embodiments set forth herein; rather, these exemplary embodiments are provided so that this disclosure is thorough and complete, and conveys the concept of the invention to those skilled in the art.

The thickness of several layers and regions shown referring to the accompanied drawings are just for the clarity in the description of the invention. In addition, in the following description referred to as “existing/adapted/formed ‘on’ a layer or substrate,” it may indicate that it is in direct contact with other layer or substrate or that a third layer is interposed therebetween. In contrast, if an element is referred to as being “directly on” another element, then no other intervening elements are present.

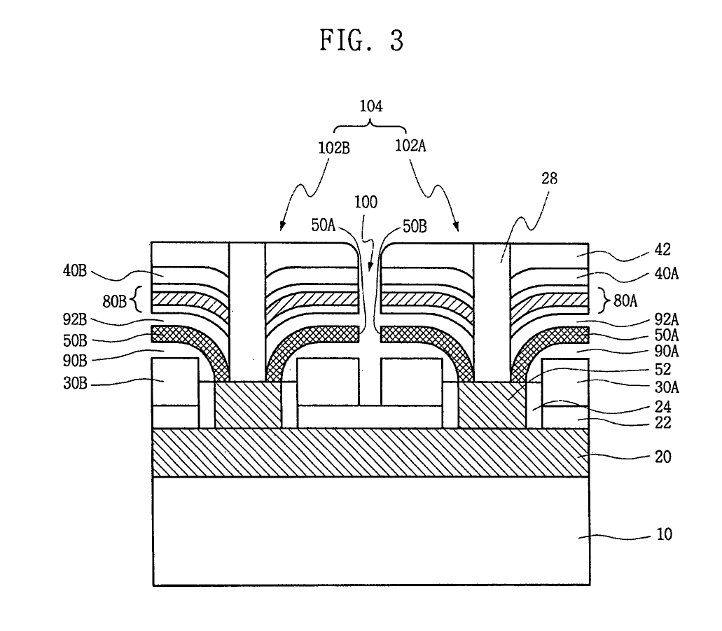

FIG. 2 is a perspective view of a multibit electro-mechanical memory device according to an embodiment of the invention. FIG. 3 is a sectional view taken along a line I˜I′ of FIG. 2.

Referring to FIGS. 2 and 3, a plurality of bit lines 20 are formed in a first direction on a substrate 10 of a given flat face. For example, in one embodiment, the substrate 10 is formed including an insulation substrate, or, in another embodiment, the substrate is a semiconductor substrate having a certain degree of dominant flexibility. The plurality of bit lines 20 include at least one of conductive metal material, and a crystal silicon or polysilicon material doped with conductive impurity, the conductive metal material including at least one of gold, silver, copper, aluminum, tungsten, tungsten silicide, titanium, titanium nitride, tantalum, tantalum silicide, or other conductive metal or metal alloy material known to those of skill in the art.

A first interlayer insulating layer 22 is formed on the plurality of bit lines 20. For example, the first interlayer insulating layer 22 is a dielectric of electrically insulating the bit line 20, and comprises silicon oxide or silicon oxide nitride.

A first lower word line 30A and a second lower word line 30B are separated from each other by a trench 100, and are formed in a second direction on the first interlayer insulating layer 22. The first lower word line 30A and the second lower word line 30B are insulated from the substrate 10 and the plurality of bit lines 20 by the first interlayer insulating layer 22. Thus, an electric signal can be applied thereto freely from the bit lines. In an embodiment, the first and second lower word lines 30A and 30B can be formed of a prominent conductive metal material, i.e., gold, silver, copper, aluminum, tungsten, tungsten silicide, titanium, titanium nitride, tantalum, tantalum silicide, or other conductive metal or metal alloy material known to those of skill in the art, similar to materials of the bit line 20.

In an embodiment, a second interlayer insulating layer 24 electrically insulates between the first and second lower word lines 30A and 30B, and is formed in the second direction between sidewalls, each not exposed by a trench 100, of the first and second lower word lines 30A and 30B. In an embodiment, a top surface of the second interlayer insulating layer 24 has a same or similar height as a height of top surfaces of the first and second lower word lines 30A and 30B. In another embodiment, a top surface of the second interlayer insulating layer 24 has a height less than a height of top surfaces of the first and second lower word lines 30A and 30B. In an embodiment, the second interlayer insulating layer 24 comprises a silicon oxide layer.

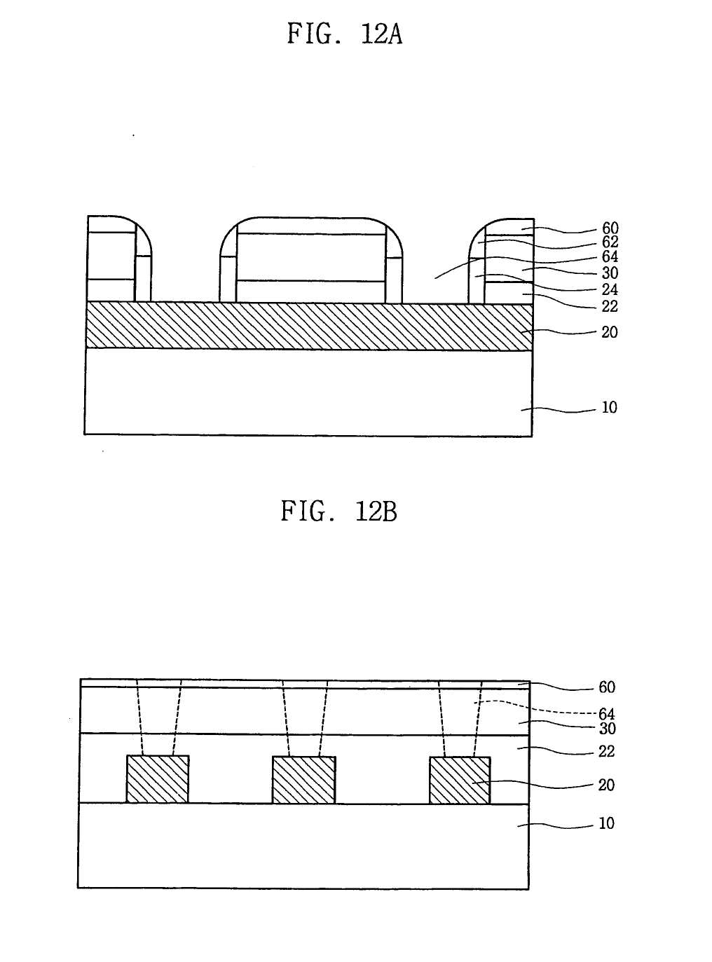

In an embodiment, at least a portion of the second interlayer insulating layer 24 is removed to produce a contact hole 64 (see, for example, FIG. 12A) such that the bit line 20 is exposed. The contact hole 64 may be formed by selectively removing a portion of the second interlayer insulating layer 24 formed on the bit line 20 that is between the second interlayer insulating layer 24 formed in the second direction and the bit line 20 formed in the first direction. A pad electrode 52 is formed inside the contact hole 64 to be electrically connected to the bit line 20. Here, the pad electrode 52 is formed with the same or similar height as a height of the second interlayer insulating layer 24 inside the contact hole 64. That is, the pad electrode 52 can be insulated from the first and second lower word lines 30A and 30B by the second interlayer insulating layer 24. In an embodiment, the pad electrode 52 may be formed to include a prominent conductive metal material, i.e., gold, silver, copper, aluminum, tungsten, tungsten silicide, titanium, titanium nitride, tantalum, tantalum silicide, or other conductive metal material known to those of skill in the art, similar to materials used to form the bit line 20.

First and second cantilever electrodes 50A and 50B are adapted to correspond to a level of an upper part of the first and second lower word lines 30A and 30B, respectively, and are formed on both sides of the pad electrode 52, in an arch or curved configuration, over first and second lower voids 90A and 90B, respectively, which are formed above the first and second word lines. The first and second cantilever electrodes 50A and 50B are supported by the pad electrode 52, and, in an embodiment, the first and second cantilevers 50A and 50B are bent in a quarter-circular arc on an upper part of the pad electrode 52.

In an embodiment, a plurality of cantilever electrodes 50 are formed on the substrate with some layers interposed therebetween. Each of the plurality of cantilever electrodes is separated into two sections by a trench. One of the two sections is referred to a first cantilever electrode 50A and the other is referred to a second cantilever electrode 50B. In other words, first cantilever lines 50A and second cantilever electrodes 50B are alternately disposed. In an embodiment, first portions of the first and second cantilever electrodes 50A and 50B extend from the pad electrode 52, and second portions of the first and second cantilever electrodes 50A and 50B are formed to curve in the first direction, i.e., X-axis direction, that is, in a sector shape with a rotation angle of about 90 degrees relative to the pad electrode 52. Here, the first portions of the first and second cantilever electrodes 50A and 50B extend from the pad electrode 52 at a predefined height or more in a third (Z-axis) direction that is perpendicular to a plane formed by the first (X-axis) direction and the second (Y-axis) direction.

Accordingly, in a multibit electro-mechanical memory device according to an embodiment of the invention, portions of the first and second cantilever electrodes 50A and 50B are in a direction that is parallel to that of the bit line 20, for example, in the first direction, and, therefore, the first and second cantilever electrodes 50A and 50B have an increased length due to its arched configuration. In particular, the first and second cantilever electrodes 50A and 50B have an increased three-dimensional length, by being curved in the third (Z-axis) direction extending above the pad electrode 52 on the bit line 20, thereby reducing a plane size of memory device, for example, a size of a plane formed by the first (X-axis) direction and the second (Y-axis) direction, and thereby increasing an integration of the memory device.

In an embodiment, the first and second cantilever electrodes 50A and 50B may be curved in the direction of the first and second lower word lines 30A and 30B by an electrostatic force generated in an electric field that is induced in the first and second lower voids 90A and 90B. That is, when a given amount of charge having mutually different polarities is applied to between the first and second cantilever electrodes 50A and 50B, and the first and second lower word lines 30A and 30B, the first and second cantilever electrodes 50A and 50B, can be curved in the third direction, i.e., Z-axis direction, by the electrostatic force corresponding to an attractive force. The third direction can be parallel to the first and second directions, or the third direction can be transverse to the first and/or second directions. At this time, the voids 90A, 90B above the first and second cantilever electrodes 50A and 50B, and the voids 92A, 90B below the first and second cantilever electrodes 50A and 50B permit the first and second cantilever electrodes 50A and 50B to be curved up and down above the first and second lower word lines 30A and 30B. Furthermore, the first and second cantilever electrodes 50A and 50B are partially curved arching or otherwise extending from the third direction to the first direction above the pad electrode 52, and thus, can be smoothly curved rather than a conventional straight-line type above the first and second lower word lines 30A and 30B.

Accordingly, in a multibit electro-mechanical memory device according to an embodiment of the invention, even when the length of first and second cantilever electrodes 50A and 50B is reduced in the first direction to a given length or below, the first and second cantilever electrodes increase in the third direction, therefore a switching distance is prevented from becoming large as compared with the length of the first and second cantilever electrodes 50A and 50B, thereby preventing the first and second cantilever electrodes 50A and 50B from being easily broken down, and so increasing reliability in memory devices.

In an embodiment, the first and second cantilever electrodes 50A and 50B may be formed of titanium, titanium nitride, or carbon nanotube material, or other material known to those of skill in the art as possessing the characteristics necessary to form a cantilever electrode. The titanium and the titanium nitride are not easily oxidized even though exposed to air by the first and second lower voids 90A and 90B, and are not transformed even though they have a given level of curvature, as conductive metal having an elastic force more than a plasticity/elasticity coefficient. The carbon nanotube is tube-shaped, and is formed by joining together six-sided shapes each constructed of 6 carbon atoms, such that the six-sided shapes are associated with one another. A diameter of the nanotube ranges from just several nanometers to tens of nanometers; hence, the term “carbon nanotube.” Further, in the carbon nanotube, electrical conduction properties are similar to those of copper, and a heat conduction properties are similar to those of diamond, which is most prominent therefor in the natural world, and the stiffness of the carbon nanotube is more than 100 times that of steel. Carbon fiber is cut against the transformation of even 1%, but carbon nanotube has a restoring force to endure even the transformation of 15% or more.

First and second trap sites 80A and 80B are suspended above the first and second cantilever electrodes 50A and 50B at a height of the first and second upper voids 92A and 92B between the first and second cantilever electrodes 50A and 50B and first and second upper word lines 40A and 40B, which are formed in the second direction. The first trap site 80A is separated from the second trap site 80B, and the first upper word line 40A is separated from the second upper word line 40B, by the trench 100. Further, sidewalls of the first and second trap sites 80A and 80B and the first and second upper word lines 40A and 40B, the sidewalls being on opposite sides of the trench 100, are curved corresponding to and with a given distance from the first and second cantilever electrodes 50A and 50B adapted on the pad electrode 52. In the first and second trap sites 80A and 80B, a given amount of charge applied through the first and second upper word lines 40A and 40B is tunneled and trapped inside thereof so that the trapped charge can be always held even when there is no charge applied from the outside. For example, the first and second trap sites 80A and 80B are formed including a thin film of ‘ONO (Oxide-Nitride-Oxide)’, wherein a first silicon oxide 82, silicon nitride 84 and second silicon oxide 86 are stacked on the first and second upper voids 92A and 92B. For example, the first and second upper word lines 40A and 40B may be formed of prominent conductive metal material, i.e., gold, silver, copper, aluminum, tungsten, tungsten silicide, titanium, titanium nitride, tantalum, tantalum silicide, or other conductive metal material known to those of skill in the art, like that of the first and second lower word lines 30A and 30B.

On the other hand, when a given charge is applied to the first and second upper word lines 40A and 40B, the charge is tunneled and captured by the first and second trap sites 80A and 80B. Then, the first and second cantilever electrodes 50A and 50B are curved upward so that the tip of the first and second cantilever electrodes 50A and 50B are in contact with the first and second trap sites 80A and 80B, by an electrical field induced by the charge applied to the first and second upper word lines 40A and 40B and the charge captured by the first and second trap sites 80A and 80B.

Even when the charge applied to the first and second upper word lines 40A and 40B and to the first and second cantilever electrodes 50A and 50B is eliminated, the first and second cantilever electrodes 50A and 50B are maintained in a curved state, intact under the state in which the tip of the first and second cantilever electrodes 50A and 50B are in direct physical contact with the first and second trap sites 80A and 80B, by an electrical field induced by the charge captured by the first and second trap sites 80a and 80B. This is why a charge having a polarity opposite the charge captured by the first and second trap sites 80A and 80B is concentrated and induced in the tip of the first and second cantilever electrodes 50A and 50B, and an electrostatic attraction acts accordingly. Thus, the first and second cantilever electrodes 50A and 50B can be maintained in the curved state.

Accordingly, in the multibit electro-mechanical memory device according to the embodiment of the invention, first and second trap sites 80A and 80B, in which a charge applied through first and second upper word lines 40A and 40B is tunneled and trapped, are employed, and thus, even when the charge applied to the first and second upper word lines 40A and 40B and the first and second cantilever electrodes 50A and 50B is eliminated, a curved state of the first and second cantilever electrodes 50A and 50B can be maintained, thereby realizing a nonvolatile memory device.

To curve the first and second cantilever electrodes 50A and 50B in a third direction, for example, a Z-axis, or in a direction perpendicular or transverse to the first and second directions, and to maintain the curved state, the first and second upper word lines 40A and 40B to which a given charge is applied, and the first and second trap sites 80A and 80B, are stacked. Therefore, the lengths of the first and second cantilever electrodes 50A and 50B are less than those lengths of the conventional art. Further, the electrical contact portion and attractive portion applied to the conventional art can be unified on a vertical line according to an embodiment of the invention, thereby increasing integration of memory devices.

A third interlayer insulating layer 28 is formed over the second interlayer insulating layer 24 and the pad electrode 52, to support and insulate between the first and second trap sites 80A and 80B and between the first and second upper word lines 40A and 40B. In an embodiment, the third interlayer insulating layer 28 is formed containing silicon oxide, silicon nitride, or silicon oxide nitride, to electrically insulate between the first and second cantilever electrodes 50A and 50B, and between the first and second upper word lines 40A and 40B.

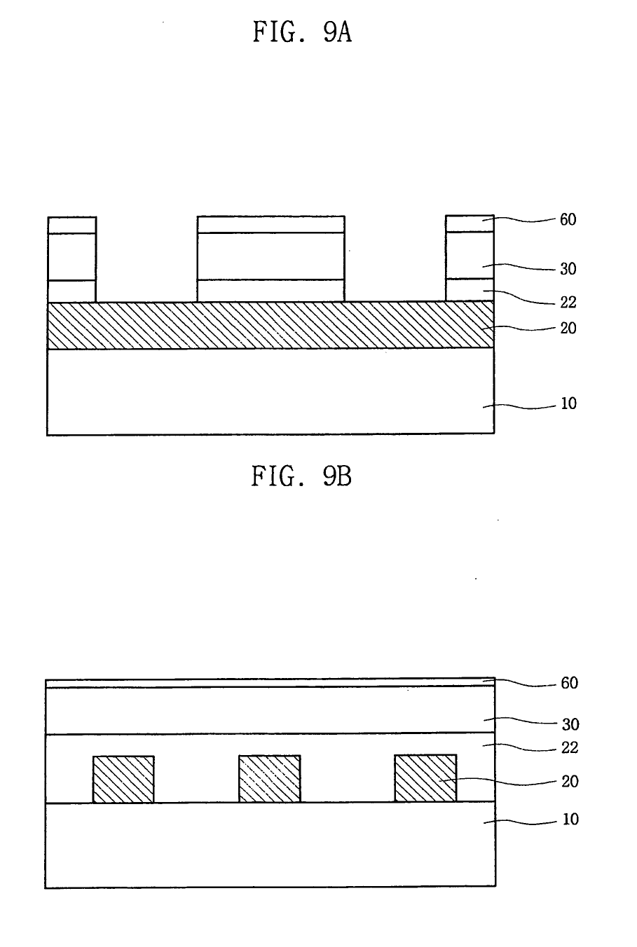

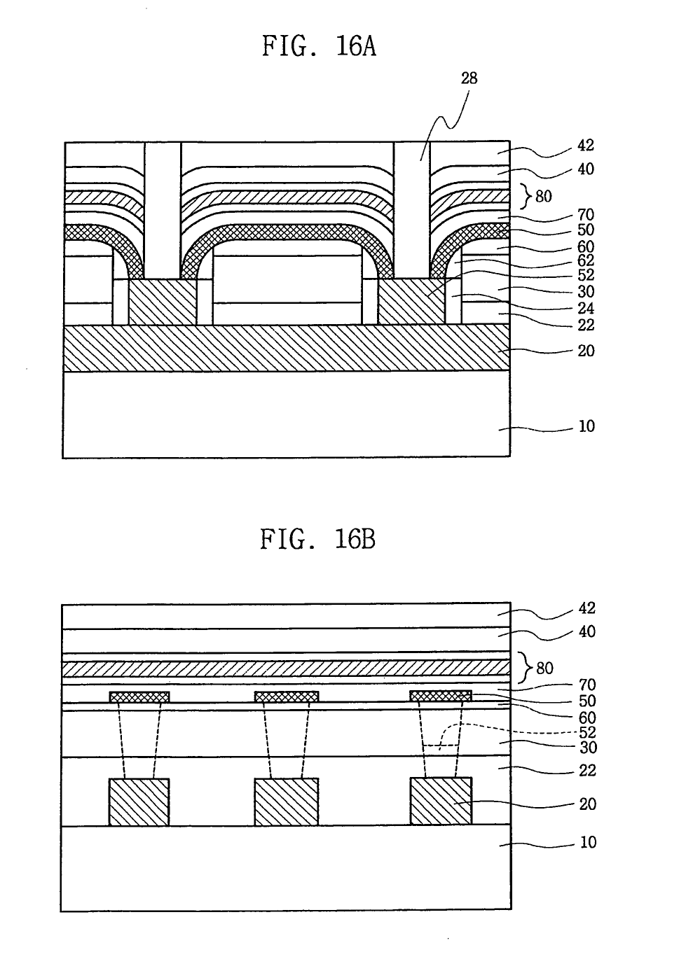

Although not shown in the drawings, the first and second lower voids 90A and 90B, and the first and second upper voids 92A and 92B, may include spaces that are formed by removing the first sacrifice layer (for example, first sacrifice layer 60 of FIG. 9A) and second sacrifice layer (for example, second sacrifice layer 70 of FIG. 16A) exposed to the trench 100. The voids may include spaces through which each tip of the first and second cantilever electrodes 50A and 50B moves in a third direction, i.e., Z-axis direction, perpendicular to the substrate 10.

Accordingly, the multibit electro-mechanical memory device comprises a unit cell 104 that is comprised of first and second memory units 102A and 102B separated from each other on the trench 100, or first and second memory units 102A and 102B separated from each other on the pad electrode 52. In an embodiment, the first and second memory units 102A and 102B adjacent mutually in first direction, i.e., X-axis direction, electrically share a single bit line 20. The first and second memory units 102A and 102B of each unit cell 104 mutually adjacent each other in the second direction, i.e., Y-axis direction, may electrically share the first lower word line 30A or second lower word line 30B, and may electrically share the first or second upper word line 40A or 40B.

The first and second cantilever electrodes 50A and 50B separated into both sides on the trench 100 or pad electrode 52 are formed as part of the unit cell 104, which is classified as first and second memory units 102A and 102B, respectively, each performing a separate switching operation. Thus, each unit cell 104 can input/output two or more bits of data.

The first and second upper word lines 40A and 40B, to which an electrical signal to switch the first and second cantilever electrodes 50A and 50B is applied, may be formed of a conductive metal material having a low resistance as compared with a conventional polysilicon material, thus reducing a power consumption and increasing throughput.

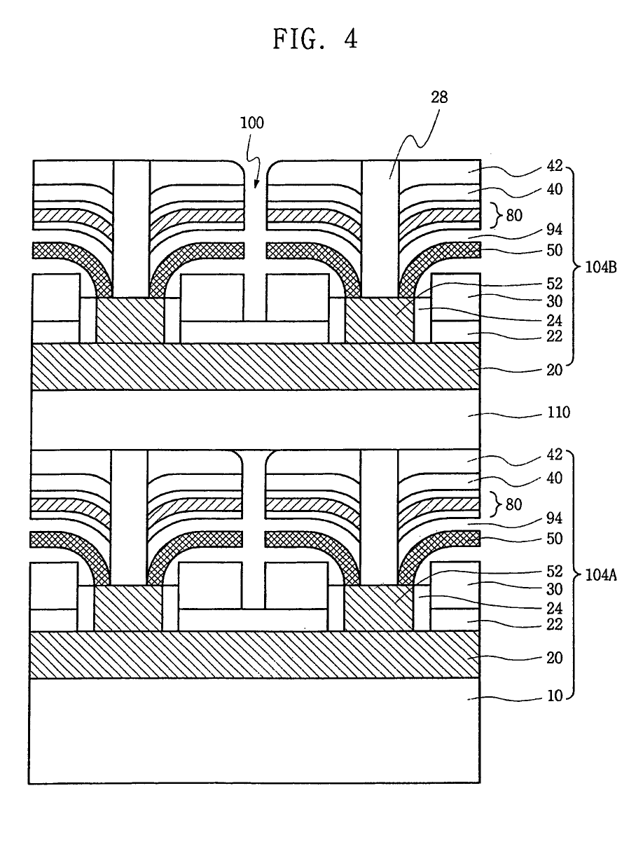

FIG. 4 is a sectional view of a stacked structure of multibit electro-mechanical memory devices shown in FIG. 3. A multibit electro-mechanical memory device according to an embodiment of the invention may be configured to have a stacked structure of the first unit cell 104A and the second unit cell 104B on a fourth interlayer insulating layer 110 formed on the first unit cell 104A. The inside of the sealed trench 100 of the first and second unit cells 104A and 104B may be in a vacant vacuum state by which the cantilever electrode 50 can move upward and downward, or may be filled with a non-reactive gas such as a nitrogen gas or an argon gas. The fourth interlayer insulating layer 110 covers an upper part of the first unit cell 104A, to distinguish the first unit cell 104A from the second unit cell 104B. The fourth interlayer insulating layer 110 is formed so as not to flow into the inside of void 94 through the trench 100. For example, the fourth interlayer insulating layer 110 is formed containing polymer material formed on third interlayer insulating layer 28 formed in an upper part of the trench 100. Although not shown in the drawing, bit line 20 of the first unit cell 104A and bit line 20 of the second unit cell 104B may be formed to have mutually different directions, or the trench 100 of the first unit cell 104A may be formed unequally relative to a formation line of the trench 100 of the second unit cell 104B.

Thus, the multibit electro-mechanical memory device according to embodiments of the invention may have the structure of laminating the second unit cell 104B on the fourth interlayer insulating layer 110 formed on the first unit cell 104A that is formed on the substrate 10, thus increasing an integration of memory devices.

An operating method of multibit electro-mechanical memory device according to an embodiment of the invention is described as follows. The first and second lower word lines 30A and 30B, and the first and second cantilever electrodes 50A and 50B, and the first and second upper word lines 40A and 40B, may be each described herein as a lower word line 30, cantilever electrode 50 and upper word line 40. The first and second lower voids 90A and 90B may be described herein as a lower void 90, and the first and second upper voids 92A and 92B as an upper void 92. Further, the lower and upper voids may be all described herein as a void 94, and reference characters may be changed in the description below.

In the multibit electro-mechanical memory device according to an embodiment of the invention, given data can be programmed, deleted, or read according to a position of cantilever electrode 50. For example, when an electrical field is not induced in the void 94, the cantilever electrode 50 can be supported horizontally at a height the same as or similar to the pad electrode 52. On the other hand, when an electrical field of a given intensity is induced in the void 94, a charge of a given intensity is concentrated on a tip of the cantilever electrode 50 by the electrical field, and the cantilever electrode 50 may be curved into a third direction that is vertical relative to the substrate 10. At this time, program, delete, and readout operations can be performed by a switching operation, wherein the tip of the cantilever electrode 50 can be attached to or detached from the lower word line 30 or trap site 80.

Accordingly, program, delete, and readout operations of each of first and second memory units 102A and 102B constituting the unit cell 104 can be individually performed by controlling a difference of voltage applied to each of the bit line 20, lower word line 30 and upper word line 40. For example, a given voltage is independently applied to the first and second lower word lines 30A and 30B, and a given voltage is independently applied to the first and second upper word lines 40A and 40B, then a state of the first and second memory units 102A and 102B may be equally programmed as “0” or “1” at the same time, or may be programmed different from each other as “0” and “1”. Through the unit cell 104 of the multibit electro-mechanical memory device according to an embodiment of the invention, input/output data of the respective first and second memory units 102A and 102B may be combined. At this time, the first and second memory units 102A and 102B electrically share one bit line 20. Thus, program and read operations of thereof cannot be simultaneously performed, and any one of the first and second memory units 102A and 102B must have an electrical use of the bit line 20 at a given time.

Thus, in the multibit electro-mechanical memory device according to an embodiment of the invention, 2 bits of data can be input to or output from a unit cell that is constructed of the first and second memory units 102A and 102B that are programmed to have the same or different state symmetrically at both sides of the trench 100 or pad electrode 52.

As described above, when a charge having a polarity opposite to a charge applied to the lower word line 30 and trap site 80 is applied, the cantilever electrode 50 is curved to be in contact with the trap site 80 by an electrostatic force acting as an attractive force. Further, when a charge having the same polarity as a charge applied to the lower word line 30 and trap site 80 is applied, the cantilever electrode 50 can be separated from the trap site 80 by an electrostatic force acting as a repulsive force. When the cantilever electrode 50 is curved so that the cantilever electrode 50 is in contact with the trap site 80, it should overcome an elasticity or restoring force of a given intensity. The elastic force or restoring force generally depends upon Hook's law proportionate to a movement distance, and the electrostatic force is based on Coulomb's law proportionate to the square of movement distance. The curved direction and movement direction of the cantilever electrode 50 may be each decided by an electrostatic force generated depending upon a polarity of charge and charge amount applied to the lower word line 30 and trap site 80.

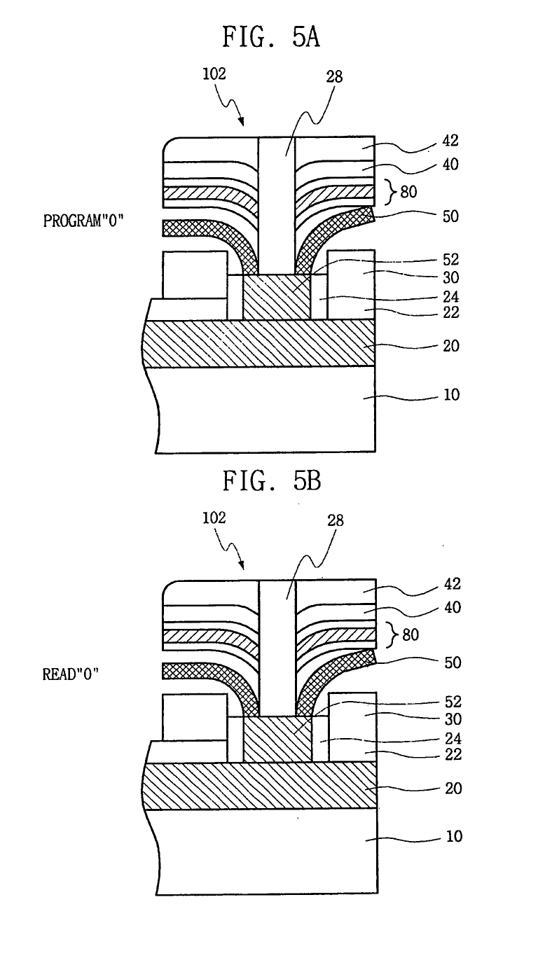

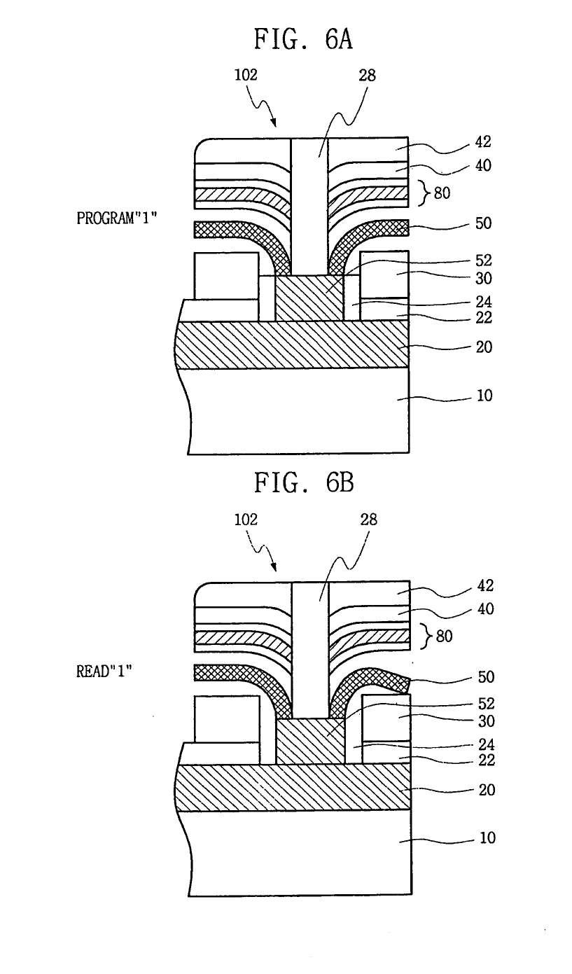

FIGS. 5A to 6B are sectional views providing operations of programming to or reading data out of a multibit electro-mechanical memory device according to an embodiment of the invention.

As shown in FIGS. 5A and 5B, to program data corresponding to ‘0’ in a multibit electro-mechanical memory device according to an embodiment of the invention, a first voltage, i.e., Vpull-in, is applied to between the upper word line 40 and the bit line 20, and so tip of cantilever electrode 50 is curved upward to contact with trap site 80. At this time, programming data corresponding to ‘0’ may be called ‘0’ program. That is, a first voltage having a given intensity is applied to between the bit line 20 and the upper word line 40 and so the tip of the cantilever electrode 50 is curved to be in contact with the trap site 80, thereby programming data corresponding to ‘0’. Further, a second voltage induced between the bit line 20 and the upper word line 40, and third voltage induced to between the bit line 20 and the lower word line 30, are compared, and when the second voltage is greater, data corresponding to ‘0’ can be read out. This is why a distance between the cantilever electrode 50 electrically connected to the bit line 20 and the upper word line 40 is shorter than a distance between the cantilever electrode 50 and the lower word line 30 and so the voltage is proportionate to an inverse number of the distance.

Consequently, in a multibit electro-mechanical memory device according to an embodiment of the invention, a first voltage having a given intensity is applied to the cantilever electrode 50 electrically connected to the bit line 20 and the upper word line 40 so that the tip of cantilever electrode 50 is curved to contact with the trap site 80, thus programming data corresponding to ‘0’. Additionally, the second voltage induced between the bit line 20 and the upper word line 40, and the third voltage induced to between the bit line 20 and the lower word line 30, are compared, and when the second voltage is greater, data corresponding to ‘0’ can be read out.

As shown in FIGS. 6A and 6B, to program data corresponding to ‘1’ in a multibit electro-mechanical memory device according to an embodiment of the invention, a fourth voltage, i.e., Vpull-out, of a given intensity is applied to between the lower word line 30 and the bit line 20, and so the tip of cantilever electrode 50 is separated from the trap site 80, thus to return to a horizontal state of the cantilever electrode 50. When the tip of the cantilever electrode 50 is already separated from the trap site 80, it does not matter that the fourth voltage is not applied. Programming data corresponding to ‘1’ may be called “PROGRAM ‘1’”. Further, second voltage induced to between the bit line 20 and the upper word line 40, and the third voltage induced to between the bit line 20 and the lower word line 30, are compared, and when the second voltage is greater than the third voltage, data corresponding to ‘1’ can be read out. In reading data corresponding to ‘1’, since the cantilever electrode 50 is positioned near the lower word line 30 as compared with the upper word line 40, the cantilever electrode 50 can be curved to electrically contact with the lower word line 30 by an electrostatic force acting as an attractive force between the cantilever electrode 50 and the lower word line 30.

Therefore, in the multibit electro-mechanical memory device according to embodiments of the invention, data of ‘0’ or ‘1’ can be programmed according to either a contact state or separated state between the tip of cantilever electrode 50 and the trap site 80, and data of ‘0’ or ‘1’ can be read out corresponding to a curved direction of the cantilever electrode 50.

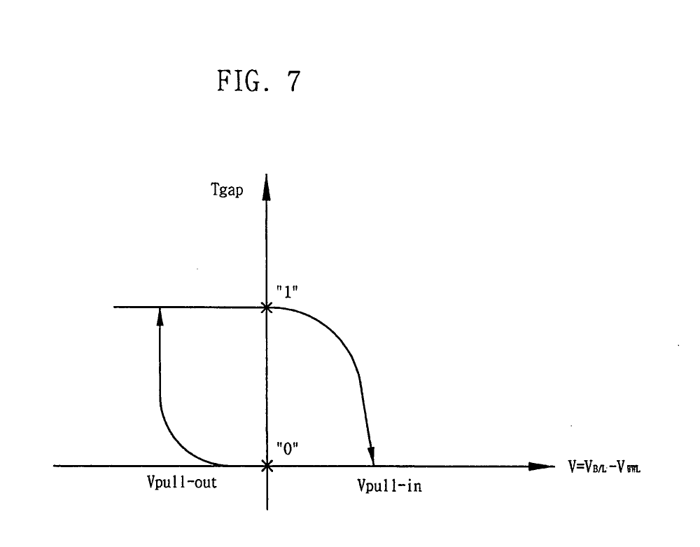

FIG. 7 is a graph illustrating a correlation between a voltage applied through the bit line 20 and the upper word line 40 and a movement distance of the tip of cantilever electrode 50 in a multibit electro-mechanical memory device according to an embodiment of the invention. When a voltage of “Vpull-in” having a positive value is applied between the bit line 20 and the upper word line 40, the tip of cantilever electrode 50 is curved up to contact with the trap site 80 and thus data corresponding to ‘0’ is programmed. When a voltage of “Vpull-out” having a negative value is applied to between the bit line 20 and the upper word line 40, the tip of cantilever electrode 50 is separated from the trap site 80 and thus data corresponding to ‘1’ can be programmed. The x-axis indicates the magnitude of voltage, and the y-axis indicates a movement distance Tgap of the tip of cantilever electrode 50 from the surface of the trap site 80 to the lower word line 30. When a voltage of “Vpull-in” having a positive value or a voltage of “Vpull-out” having a negative value is applied to the upper word line 40 and the cantilever electrode 50 connected to the bit line 20, the tip of cantilever electrode 50 is in contact with or separated from the trap site 80, thus programming digital data corresponding to 1 bit having a value of ‘0’ or ‘1’.

At this time, the voltage of “Vpull-in” and “Vpull-out” may be decided by the following formula.

(Mathematical Formula)

V=V_{B/L}−V_{WWL}

The “V” indicates voltage of “Vpull-in” or “Vpull-out”, and “VB/L” designates a voltage applied to the bit line 20, and “V_{WWL}” indicates a voltage applied to the upper word line 40. At this time, the voltage of “Vpull-in” has a positive value, and the voltage of “Vpull-out” has a negative value. For example, when absolute values of the voltage of “Vpull-in” and the voltage of “Vpull-out” are the same or similar to each other, a voltage of ½*“Vpull-in” is applied to the bit line 20 and a voltage of ½*“Vpull-out” is applied to the upper word line 40 in programming data corresponding to a value of ‘0’, thereby electrically contacting the tip of cantilever electrode 50 to the upper word line 40 through an upward curved operation of the cantilever electrode 50.

Furthermore, in programming data corresponding to ‘1’, a voltage of ½*“Vpull-out” is applied to the bit line 20 and a voltage of ½*“Vpull-in” is applied to the upper word line 40, thereby separating a cantilever electrode 50 from the upper word line 40. Although not shown in the drawings, bit line 20, lower word line 30 and upper word line 40, to which the voltage of “Vpull-in” or “Vpull-out” is not applied, have a grounded state.

A method of manufacturing a multibit electro-mechanical memory device described above according to an embodiment of the invention is described as follows.

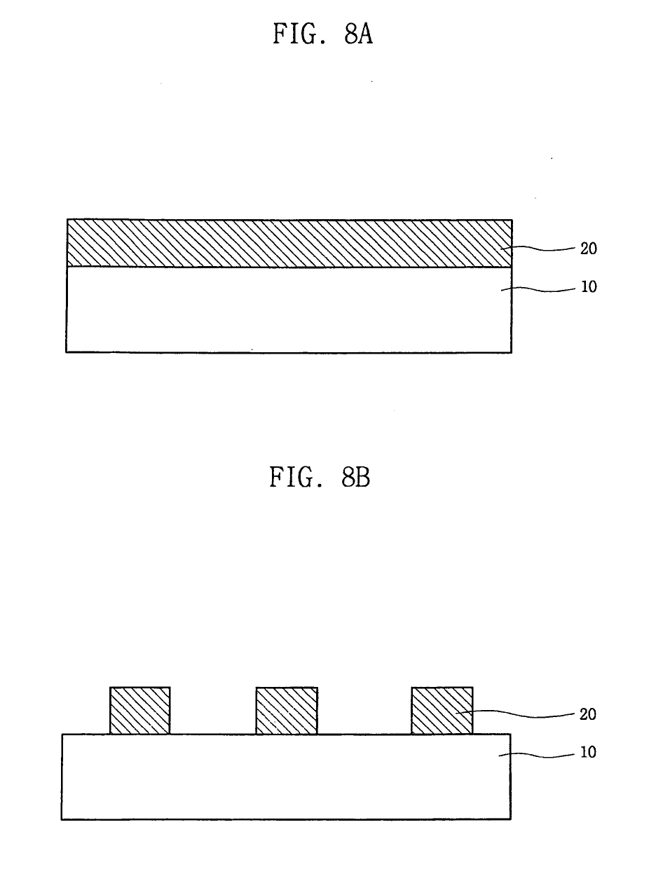

FIGS. 8A to 18B are sectional views illustrating processes provided to manufacture a multibit electro-mechanical memory device according to an embodiment of the invention. FIGS. 8A to 18A are sectional views of sequential processes taken along a line I˜I′ of FIG. 2 and FIGS. 8B to 18B are sectional views of sequential processes taken along a line II˜II′ of FIG. 2.

As shown in FIGS. 8A and 8B, at least one bit line 20 having a given thickness is formed in a first direction on a substrate 10. In an embodiment, when two or more bit lines 20 are formed, bit lines 20 are formed in parallel in the first direction on the substrate 10. In an embodiment, the bit line 20 may containing a conductive metal film such as gold, silver, copper, aluminum, tungsten, tungsten silicide, titanium, titanium nitride, tantalum, tantalum silicide formed by a physical vapor deposition (PVD) or chemical vapor deposition (CVD), or a polysilicon film or crystal silicon film doped with conductive impurity, or other conductive metal or metal alloy known to those of skill in the art. Although not shown in the drawings, the bit line 20 may be formed by anisotropically etching the polysilicon layer or the conductive metal layer formed with a given thickness on an entire face of the substrate 10 through a dry etching method that uses a photoresist pattern or first hard mask layer (not shown) as an etch mask layer, the photoresist pattern or first hard mask layer being for shielding thereon to produce a given line width. For example, reactive gas used for the dry etching method of the conductive metal layer or polysilicon layer may contain a strong acid gas mixed with HF, fluorosulfuric acid, sulphuric acid or nitric acid. In an embodiment, the bit line 20 is formed to have a thickness of about 200 Å and a line width of about 50 Å.

As shown in FIGS. 9A and 9B, first interlayer insulating layer 22, lower word line 30 and first sacrifice layer 60 are formed having a given line width in the second direction that intersects the first direction of the bit line 20. The first interlayer insulating layer 22, the lower word line 30 and the first sacrifice layer 60 are stacked having a given thickness, and this stack is anisotropically etched and formed by a dry etching method that employs a photoresist pattern or a second hard mask layer (not shown) formed on the first sacrifice layer 60, as the etching mask. The second hard mask layer and the photoresist pattern are removed. For example, the first interlayer insulating layer 22 is formed including a silicon oxide or silicon nitride formed with a thickness of about 150 Å to about 200 Å via the CVD. Here the first interlayer insulating layer 22 may perform a function of etching stop layer in a subsequent process of forming trench 100 to isolate the lower word line 30 in a length direction. The lower word line 30 is formed including a conductive metal layer having a prominent conduction, such as gold, silver, copper, aluminum, tungsten, tungsten silicide, titanium, titanium nitride, tantalum, tantalum silicide, formed with a thickness of about 200 Å through PVD or CVD, or other conductive metal known to those of skill in the art. The first sacrifice layer 60 is formed of a polysilicon material by an atomic layer deposition or CVD, with a thickness of about 50 Å to about 150 Å. A stack comprising the first sacrifice layer 60, the lower word line 30 and the first interlayer insulating layer 22 is formed to have a line width of about 50 Å, and reactive gas used for the dry etching method to pattern the stack may be gas of FC-group such as CₓF_{y} group or CₐH_{b}F_{c} group etc. The gas of FC-group may be formed of gas such as CF₄, CHF₃, C₂F₆, C₄F₈, CH₂F₂, CH₃F, CH₄, C₂H₂, C₄F₆, etc. or a mixture thereof.

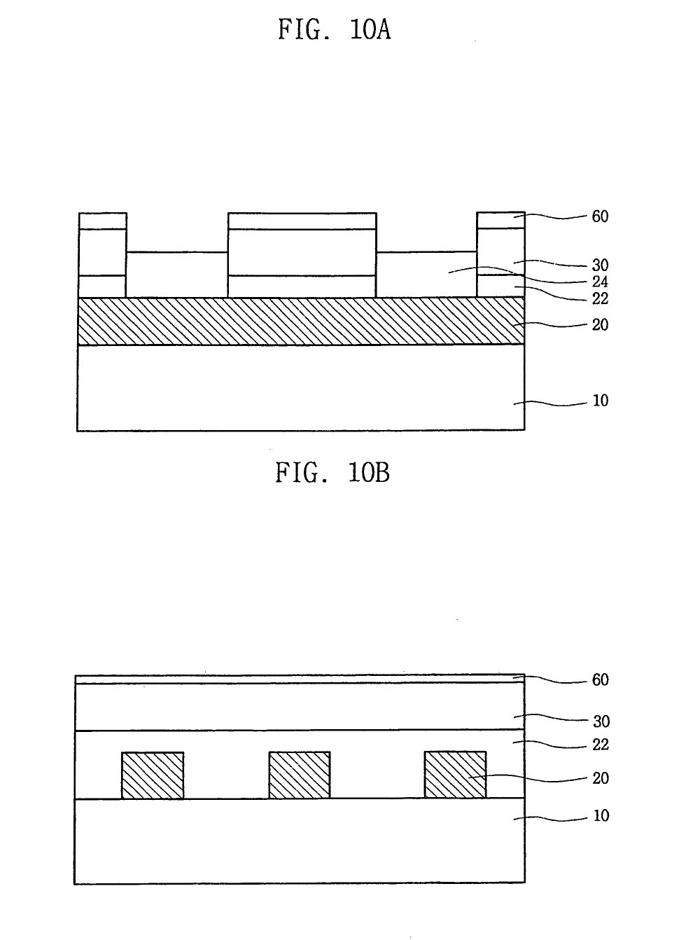

As shown in FIGS. 10A and 10B, a second interlayer insulating layer 24 is formed in an exposed region between sidewalls of the first interlayer insulating layer 22 and portions of sidewalls of the lower word line 30. Here the second interlayer insulating layer 24 is formed to electrically isolate other unit cell 104 adjacent to unit cell 104 including the lower word line 24. For example, the second interlayer insulating layer 24 may be formed by forming a silicon oxide layer filling in the stack through the CVD on an entire face of the substrate 10, removing the silicon oxide layer to become planarized to expose the first sacrifice layer 60, and executing an etchback of the silicon oxide layer to a level of the lower word line 30 or below through the dry etching method using the first sacrifice layer 60 as a mask layer.

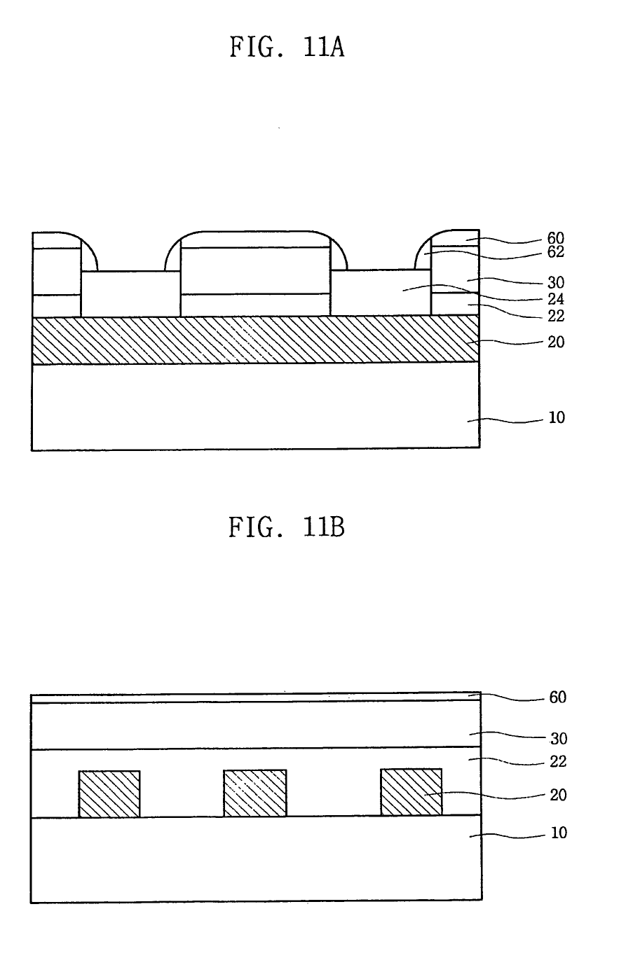

As shown in FIGS. 11A and 11B, a spacer 62 is formed on a sidewall of the lower word line 30 and a sidewall of the first sacrifice layer 60, the sidewalls of the lower word line 30 and first sacrificial layer 60 on both sides of the second interlayer insulating layer 24. The spacer 62 is formed having a given curved surface to enable the cantilever electrode 50 formed subsequently on the second interlayer insulating layer 24 to be curved from a third direction (e.g., Z-axis direction) to the first direction (e.g., X-axis direction). In an embodiment, the spacer 62 is formed of a polysilicon layer by the same or similar CVD or atomic layer deposition as that of the first interlayer insulating layer. Further, the spacer 62 may be formed to surround the sidewall of the lower word line 30 and the first sacrifice layer 60, by evenly forming the polysilicon layer on an entire face of the substrate 10 on which the second interlayer insulating layer 24, the lower word line 30 and the first sacrifice layer 60 have been formed and by anisotropically removing the polysilicon layer by the dry etching method.

As illustrated in FIGS. 12A and 12B, a contact hole 64 is formed by removing a portion of the second interlayer insulating layer 24 to selectively expose the bit line 20. The second interlayer insulating layer 24 is etched by a dry etching method using the spacer 62 as a mask layer. Here, the contact hole 64 is formed between sidewalls of the etched second interlayer insulating layer 24 that remain formed under the spacer 62 so as not to expose the sidewall of the first interlayer insulating layer 22 and the lower word line 30 between mutually adjacent unit cells 104. This is why the pad electrode 52 subsequently formed inside the contact hole 64 can apply a charge applied via the bit line 20 independently of a charge applied to the trap site 80 and the lower word line 30. In an embodiment, a contact hole 64 may be formed by removing the second interlayer insulating layer 24 through a self-alignment of dry etching method using the spacer 62 as a mask layer. Here, a source gas used in the dry etching method contains HBr having a high selection ratio of silicon oxide layer as compared with polysilicon material.

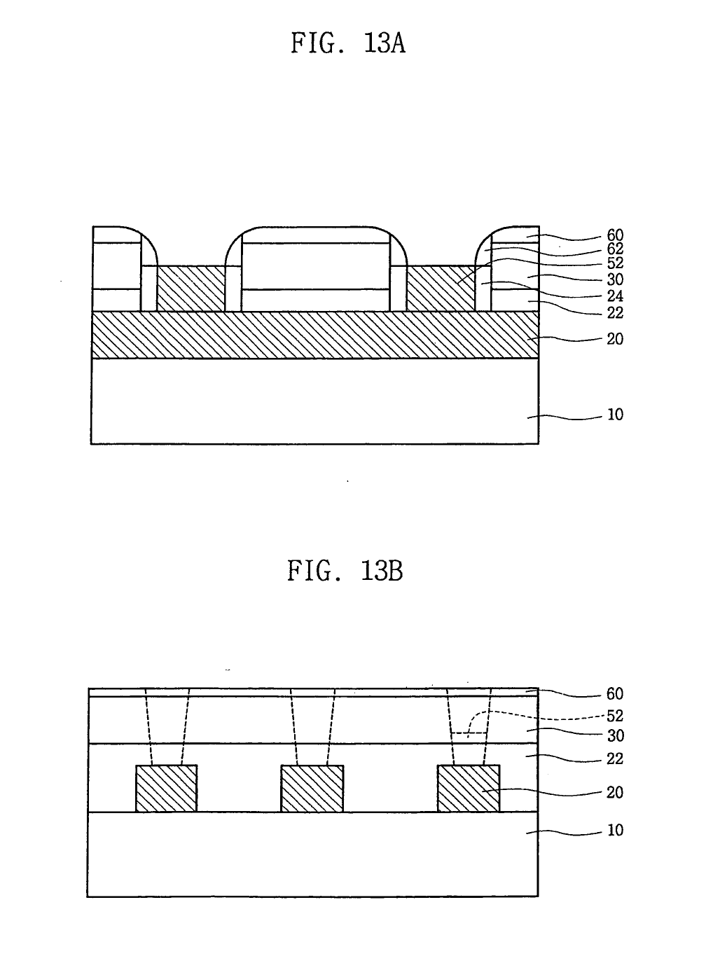

As shown in FIGS. 13A and 13B, a pad electrode 52 is formed filling in the inside of the contact hole 64. The pad electrode 52 is electrically connected to the bit line 20 exposed to the contact hole 64. Although not shown in the drawings, at least one conductive layer may be further formed to produce an ohmic contact between the bit line 20 and the pad electrode 52. In an embodiment, the pad electrode 52 may be produced by forming a conductive metal layer filling the contact hole 64, the pad electrode 52 being of a given thickness, and formed by PVD or CVD, and produced by removing the conductive metal layer to be planarized so as to expose the first sacrifice layer 60, and by selectively removing the conductive metal layer to expose the spacer 62. Thus, the pad electrode 52 is formed to have the same or similar height as the second interlayer insulating layer 24. Further, an oxide removing process or etching process may be further executed to remove an oxide layer formed on the surface of the bit line 20 exposed to the contact hole 64, before forming the pad electrode 52.

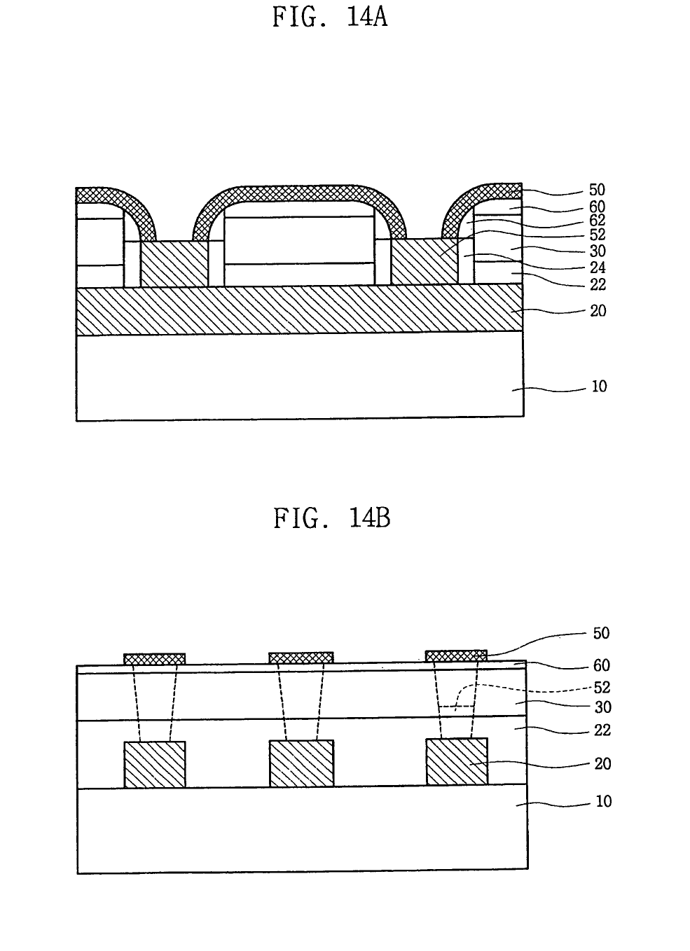

As shown in FIGS. 14A and 14B, a cantilever electrode 50 with a given line width is formed on the pad electrode 52, and extends in a third direction. A portion of the cantilever electrode conforms to the curved surface of the spacer 62, and crosses an upper part of the first sacrifice layer 60, lower word line 30 and first interlayer insulating layer 22 in the first direction. The cantilever electrode 50 has the same or similar line width as the bit line 20 and is electrically coupled to the bit line 20 on the pad electrode 52, spacer 62 and first sacrifice layer 60, and thus may be referred to hereinafter as an upper bit line. At this time, the upper bit line may be formed as the cantilever electrode 50 such that a node is divided by trench 100 formed in a subsequent process. In an embodiment, the cantilever electrode 50 may be formed containing titanium, titanium nitride, or carbon nanotube, or similar materials known to those of skill in the art, to have a thickness of about 30 Å through about 50 Å through the PVD, CVD or electrical discharge. At this time, the cantilever electrode 50 may be patterned and formed through the dry etching method that employs a photoresist pattern or third hard mask layer (not shown) as an etching mask, the photoresist pattern or third hard mask layer being for shielding the titanium, titanium nitride or carbon nanotube formed on the bit line 20. The third hard mask layer is removed in the patterning of the cantilever electrode 50.

Accordingly, in a method of manufacturing a multibit electro-mechanical memory device according to an embodiment of the invention, cantilever electrode 50 curved with a given curvature from the third direction to the first direction is formed above the pad electrode 50 electrically connected to the bit line 20 formed in the first direction on the substrate 10, thereby increasing an integrated level of memory devices.

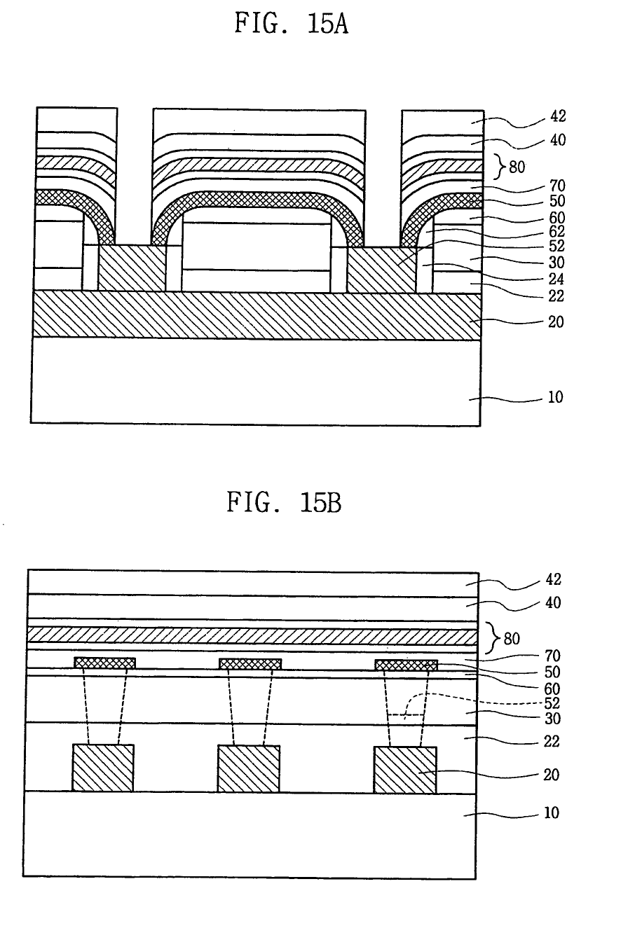

As illustrated in FIGS. 15A and 15B, a second sacrifice layer 70, trap site 80 and upper word line 40 are adapted in parallel with, and are formed on the cantilever electrode 50, the spacer 62, first sacrifice layer 60, lower word line 30, and first interlayer insulating layer, and are formed in the second direction. The second sacrifice layer 70, trap site 80 and upper word line 40 are formed herein symmetrically with regard to the spacer 62, the first sacrifice layer 60 and the lower word line 30, with the cantilever electrode 50 therebetween. For example, the second sacrifice layer 70 is formed of polysilicon material by an atomic layer deposition or CVD like the first sacrifice layer 60, and has the thickness of about 50 Å to about 150 Å. The trap site 80 is formed including a first silicon oxide layer 82, silicon nitride layer 84 and second silicon oxide layer 86 each with the thickness of about 100 Å, 200 Å and 100A by the CVD. The upper word line 40 is formed with a thickness of about 200 Å. The second sacrifice layer 70 and the upper word line 40 are formed to each have a line width of about 50 Å. At this time, the second sacrifice layer 70, trap site 80 and upper word line 40 may be formed as follows. On an entire face of the substrate 10 on which the cantilever electrode 50 has been formed, a polysilicon layer of a given thickness, first silicon oxide layer 82, silicon nitride layer 84, second silicon oxide layer 86, conductive metal layer and fourth mask layer 42 are sequentially stacked by the CVD or other deposition process.

Then, a photoresist pattern is formed, the photoresist pattern being for shielding the fourth hard mask layer 42 that is formed on the spacer 62, cantilever electrode 50, first sacrifice layer 60, lower word line 30 and first interlayer insulating layer 24. Subsequently, the fourth hard mask layer 42 is removed by the dry etching method or wet etching method that uses the photoresist pattern as an etching mask, then the photoresist pattern is removed by an ashing process. Finally, the conductive metal layer, second silicon oxide layer 86, silicon nitride layer 84, first silicon oxide layer 82 and polysilicon layer are sequentially etched anisotropically through the dry or wet etching method that uses the fourth hard mask layer 42 as the etching mask, thereby forming the upper word line 40, trap site 80 and second sacrifice layer 70. At this time, in patterning the second sacrifice layer 70, trap site 80 and upper word line 40, portions of the cantilever electrode 50 formed on the pad electrode 52 may be exposed.

As shown in FIGS. 16A and 16B, a third interlayer insulating layer 28 of a given thickness is formed on the cantilever electrode 50 formed on the pad electrode 52, the fourth hard mask layer 42 and the second interlayer insulating layer 24, and the third interlayer insulating layer 28 is planarized to expose the fourth hard mask layer 42. The third interlayer insulating layer 28 has the same as or similar thickness to the second sacrifice layer 70, trap site 80 and upper word line 40, or has a thickness thicker than that of the sacrifice layer 70, trap site 80 and upper word line 40. Thus, when the second sacrifice layer 70 is removed in a subsequent process, the third interlayer insulating layer 28 supports a side face of the trap site 80 and the upper word line 40, thereby adapting the trap site 80 and the upper word line 40, which are supported by the third interlayer insulating layer 28, and which suspend above the cantilever electrode 50. In an embodiment, the second interlayer insulating layer is formed including a silicon oxide layer formed by a plasma CVD. Further, the third interlayer insulating layer 28 may be planarized by a chemical mechanical polishing. At this time, when the third interlayer insulating layer 28 is planarized by using the upper word line 40 as an etch stop layer, the upper word line 40 formed of conductive metal layer may be damaged, thus the fourth hard mask layer 42 should be used as the etch stop layer. When the fourth hard mask layer 42 becomes excessively thin during the polishing process so as not to function as an etching mask for the succeeding process, silicon nitride may be deposited on the fourth hard mask layer 42 so that the fourth hard mask layer 42 becomes thick.

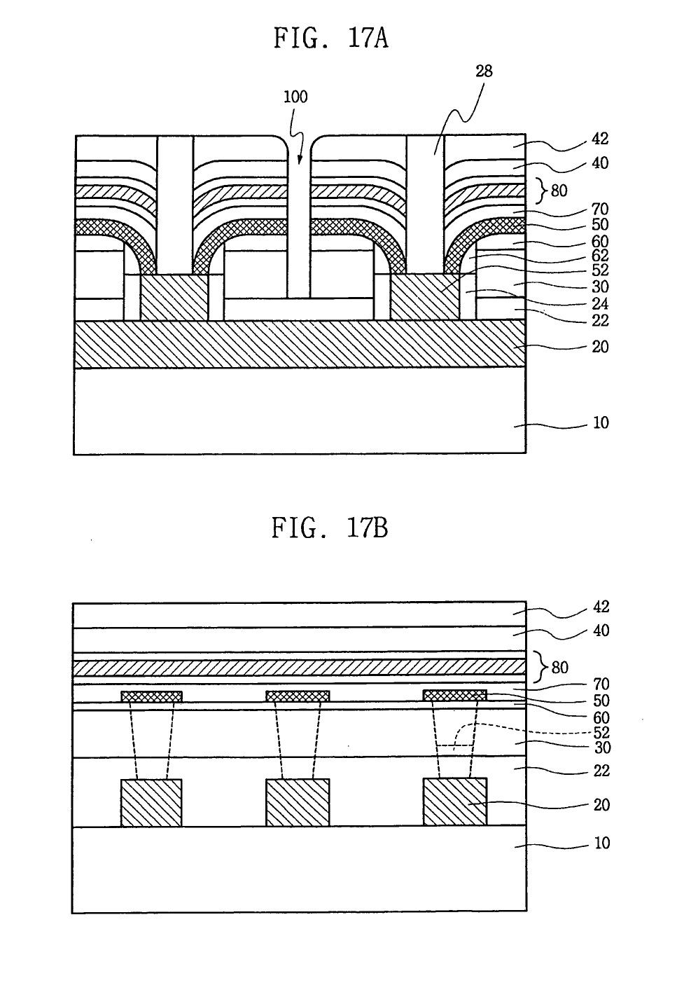

With reference to FIGS. 17A and 17B, the fourth hard mask layer 42 is etched by a dry etching method that uses a photoresist pattern as an etching mask, the photoresist pattern being for exposing, in a second direction, a center of the fourth hard mask 42 formed on the upper word line 40. And then, the photoresist pattern is removed. The upper word line 40, trap site 80, second sacrifice layer 70, cantilever electrode 50, first sacrifice layer 60 and lower word line 30 are sequentially removed by a dry etching method using the fourth hard mask layer 42 as the etching mask, thus forming trench 100 that exposes the first interlayer insulating layer. The trench 100 is formed to separate, in the second direction, the upper word line 40, trap site 80 and lower word line 30, and to separate a node of the cantilever electrode 50, and furthermore to easily remove the first and second sacrifice layers 60 and 70. For example, reactive gas used for the dry etching method may be gas of FC-group such as CₓF_{y} group or CₐH_{b}F_{c} group etc. The gas of FC-group may be gas such as CF₄, CHF₃, C₂F₆, C₄F₈, CH₂F₂, CH₃F, CH₄, C₂H₂, C₄F₆ etc. or a mixture gas thereof. The trench 100 has a given line width to separate, symmetrically in the first direction, the upper word line 40, second sacrifice layer 70, cantilever electrode 50, first sacrifice layer 60 and lower word line 30. And, in a subsequent process, etchant solution or reactive gas to isotropically eliminate the first and second sacrifice layers 60 and 70 formed in a lower part of the trap site 80 may easily flow into the trench 100. The trench 100 may be formed herein with a line width of about 30 Å to 800 Å.

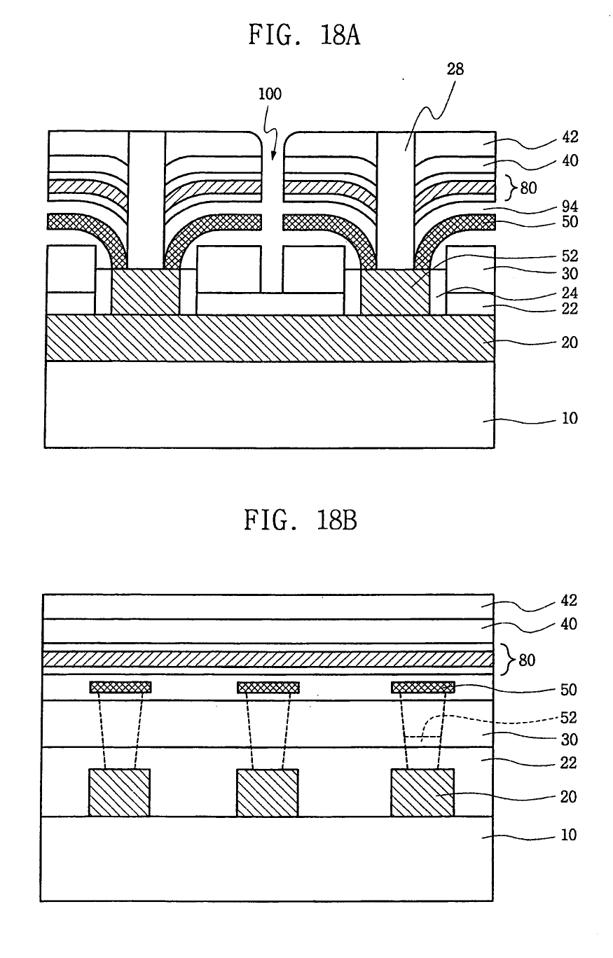

As shown in FIGS. 18A and 18B, the first sacrifice layer 60 and the second sacrifice layer 70 exposed to the trench 100 are removed, thus forming a void 94 through which the cantilever electrode 50 is suspended between the lower word line 30 and the upper word line 40. In an embodiment, the first or second sacrifice layers 60 or 70 may be isotropically etched and removed from a portion exposed to a sidewall of the trench 100 in a side direction by the wet or dry etching method. Etchant solution used for the wet etching method of the first and second sacrifice layer formed of polysilicon material may be mixture solution obtained by mixing a strong acid such as nitric acid, HF and acetic acid with deionized water by a given density. Reactive gas used for the dry etching method of the first and second sacrifice layers 60 and 70 may be gas of FC-group such as CF₄, CHF₃, etc. Etchant solution or reactive gas used for the wet or dry etching method horizontally eliminates the first sacrifice layer 60 and the second sacrifice layer 70 exposed to a sidewall of the trench 100, thereby forming the void 94 between the upper and lower word lines 40 and 30.

Although not shown in the drawing, the fourth interlayer insulating layer 110 covering an upper part of the trench 100 is sealed. The void 94 inside the sealed trench 100 may be filled with a non-reactive gas such as nitrogen in air or argon, and may be determined to have a vacuum state to increase a curved speed of the cantilever electrode 50. In an embodiment, the fourth interlayer insulating layer 110 is formed of polymer material that does not flow into the inside of the trench 100, but covers an upper part of the third interlayer insulating layer 28 or the upper word line 40 formed on the trench 100. In addition, a memory device having a multilayer structure may be manufactured by sequentially forming another bit line 20, lower word line 30, cantilever electrode 50 and upper word line 40 on an upper part of the substrate 10 on which the fourth interlayer insulating layer 110 has been formed.

Consequently, in a method of manufacturing a multibit electro-mechanical memory device according to an embodiment of the invention, plural lower word lines 30, cantilever electrodes 50, trap sites 80 and upper word lines 40 can be formed symmetrically on both sides of the trench 100 in a second direction, intersect an upper part of bit line 20 formed in a first direction on the substrate 10, thereby increasing an integrated level of the memory device.

As described above, according to an embodiment of the invention, first and second cantilever electrodes formed in a direction parallel with a bit line formed in the first direction are increased in a three-dimensional length, being curved in the third direction above the pad electrode formed on the bit line, thereby reducing a plane size of memory device and thus increasing an integration of memory devices.

Additionally, according to an embodiment of the invention, even when the length of first and second cantilever electrodes is reduced in the first direction to a given length or below, the first and second cantilever electrodes increase in the third direction, therefore a switching distance is prevented from becoming large as compared with the length of the first and second cantilever electrodes, thereby preventing the first and second cantilever electrodes from being easily broken down and so increasing reliability in memory devices.

In addition, first and second cantilever electrodes separated into both sides of a trench or pad electrode are formed in a unit cell that is classified as first and second memory units performing a separate switching operation, thus there is an effect to two or more bits of input/output data for each unit cell.

While the present invention has been particularly shown and described with reference to exemplary embodiments thereof, it will be understood by those skilled in the art that various changes in form and details may be made therein without departing from the spirit and scope of the present invention as defined by the appended claims. Accordingly, these and other changes and modifications are seen to be within the true spirit and scope of the invention as defined by the appended claims.

What is claimed is:

1. A memory device, comprising:
a substrate;
a bit line extending in a first direction on the substrate;
a lower word line extending in a second direction, the lower word line isolated from the bit line;
a pad electrode isolated from a sidewall of the lower word line and electrically coupled to the bit line;
a cantilever electrode comprising a first portion that is supported by the pad electrode, and that extends from the pad electrode in a third direction that is transverse to the first and second directions, and further comprising a second portion that arches over an upper part of the lower word line, wherein a lower void is between the second portion of the cantilever electrode and the lower word line, and wherein the second portion of the cantilever electrode, in a first position, is curved in the first direction;
a trap site extending in the second direction above the cantilever electrode, the trap site separated from the cantilever electrode by an upper void; and
an upper word line on the trap site, the upper word line receiving a charge that enables the second portion of the cantilever electrode, in a second position, to be curved toward the trap site.

2. The device of claim 1, wherein a top surface of the pad electrode is at a same level as a top surface of the lower word line or at a level lower than the top surface of the lower word line.

3. The device of claim 1, wherein at least a portion of the lower void is adjacent a side face of the lower word line.

4. A multibit electro-mechanical memory device, comprising:
a substrate;
a bit line extending in a first direction on the substrate;
a first interlayer insulating layer on the bit line, the first interlayer insulating layer extending in a second direction perpendicular to the first direction, and insulating the bit line;
first and second lower word lines formed on the first interlayer insulating layer;
a second interlayer insulating layer between the sidewalls of the first and second portions of the first interlayer insulating layer and between sidewalls of the first and second lower word lines;
a pad electrode electrically coupled to the bit line by a contact hole formed in the second interlayer insulating layer;
first and second cantilever electrodes arching over first and second lower voids that are between the first and second cantilever electrodes and the first and second word lines, wherein the first and second cantilever electrodes are separated from each other by a trench, and are curved in a third direction that is transverse to the first and second directions;
a third interlayer insulating layer on the pad electrode;
first and second trap sites supported by the third interlayer insulating layer, wherein first and second upper voids are between the first and second trap sites and the first and second cantilever electrodes, respectively; and
first and second upper word lines on the first and second trap sites.

5. The device of claim 4, wherein a top surface of the pad electrode is at a same level as a top surface of the lower word line or at a level lower than the top surface of the lower word line.

6. The device of claim 4 wherein at least a portion of the lower void is adjacent a side face of the lower word line.

7. The device of claim 4, wherein the first and second trap sites each have a stacked structure comprising a first silicon oxide layer, a silicon nitride layer, and a second silicon oxide layer.

8. The device of claim 4, further comprising a fourth interlayer insulating layer that seals the trench at an upper end part of the trench.

9. A method of manufacturing a multibit electro-mechanical memory device, the method comprising:
forming a bit line in a first direction on a substrate;
forming a first interlayer insulating layer, a lower word line and a first sacrifice layer on the substrate in a second direction perpendicular to the bit line;
forming a second interlayer insulating layer on at least a portion of a sidewall of the first interlayer insulating layer and the lower word line, and planarizing the second interlayer insulating layer;
forming a spacer on the second interlayer insulating layer, the spacer abutting a remaining portion of the sidewall of the lower word line, wherein an upper portion of the spacer abuts a sidewall of the first sacrifice layer;
forming a contact hole that selectively exposes the bit line by removing a portion of the second interlayer insulating layer by an etching method using the spacer as a mask layer;
forming a pad electrode inside the contact hole;
forming a cantilever electrode that is coupled to an upper part of the pad electrode and that conforms to an upper surface of the first sacrifice layer and the spacer;
forming a second sacrifice layer, a trap site, and an upper word line in the second direction on the cantilever electrode;
forming a third interlayer insulating layer on the pad electrode to be in contact with sidewalls of the second sacrifice layer, the trap site, and the cantilever electrode;
forming a trench to expose the first interlayer insulating layer by removing, in the second direction, portions of the upper word line, the trap site, the second sacrifice layer, the cantilever electrode, the first sacrifice layer and the lower word line; and
forming a void above and below the cantilever electrode by removing the first sacrifice layer, the spacer and the second sacrifice layer exposed to the trench.

10. The method of claim 9, wherein forming the second interlayer insulating layer comprises:
forming a silicon oxide layer having a given thickness on an entire face of the substrate on which the first interlayer insulating layer, the lower word line and the first sacrifice layer have been formed;
removing the silicon oxide layer to become planarized to expose the first sacrifice layer; and
removing the silicon oxide layer to partially expose the sidewalls of the first sacrifice layer and the lower word line.

11. The method of claim 9, wherein forming the spacer comprises:
forming a thin film of polysilicon material with a given thickness on an entire face of the substrate on which the second interlayer insulating layer and the first sacrifice layer have been formed; and
removing the thin film through an anisotropic etching method.

12. The method of claim 9, wherein the contact hole is formed by removing the spacer in a self-alignment of a dry etching method using the spacer as a mask layer.

13. The method of claim 12, wherein the dry etching method uses HBr gas as a source gas having a high etching selection ratio for silicon oxide as compared with polysilicon when the spacer is formed of polysilicon and the second interlayer insulating layer is formed of silicon oxide.

14. The method of claim 9, wherein the pad electrode is formed by forming a conductive metal filling in the contact hole, removing the conductive metal to be planarized so as to expose the first sacrifice layer, and selectively etching the conductive metal to expose the spacer.

15. The method of claim 9, further comprising forming a titanium or titanium nitride layer on the bit line exposed to the contact hole before forming the pad electrode.

16. The method of claim 9, wherein when the spacer, the first sacrifice layer and the second sacrifice layer are formed of polysilicon, the polysilicon is removed through an isotropic etching of a wet or dry etching method.

17. The method of claim 16, wherein an isotropic etching solution used in the wet etching method contains nitric acid, HF and mixture solution got by mixing acetic acid and deionized-water by a given density, and isotropic etching solution used in the dry etching method contains gas of fluoridation carbon group formed of CF₄ or CHF₃.

18. The method of claim 9, further comprising forming a fourth interlayer insulating layer shielding an upper part of the trench to seal the interior of the trench.
